(19) United States
(12) Patent Application Publication
(10) Pub. No.: US 2012/0270064 A1
(43) Pub. Date: Oct. 25, 2012

(54) SLIDE MEMBER INCLUDING DIAMOND-LIKE-CARBON FILM

(75) Inventors: Shinya OKAMOTO, Mito (JP); Itto SUGIMOTO, Hitachi (JP); Noboru BABA, Hitachiota (JP)

(73) Assignee: Hitachi, Ltd.

(21) Appl. No.: 13/449,340

(22) Filed: Apr. 18, 2012

(30) Foreign Application Priority Data
Apr. 22, 2011 (JP) 2011-095636

(51) Int. Cl. B32B 9/04; C23C 14/06; B32B 15/04; C23C 14/35

(52) U.S. Cl. 428/634; 204/192.15

(57) ABSTRACT

The object of the present invention is to provide a slide member excellent in wear resistance and highly reliable over a long period by improving the adhesion property (anti-flaking property) of a diamond-like-carbon coating in the slide member including the diamond-like-carbon coating. The sliding member includes a substrate; and a diamond-like-carbon film including layers serially stacked in order of a first layer, a second layer and a hard carbon layer, in which the substrate is formed of an alloy steel containing at least one element selected from the group consisting of V, Cr, Nb, Mo, Ta and W, in which the first layer contains at least one element selected from the group consisting of V, Cr, Nb, Mo, Ta and W, and in which the first layer adheres to the substrate.

### CLAIM OF PRIORITY

The present application claims priority from Japanese Patent application serial No. 2011-095636, filed on Apr. 22, 2011, the content of which is hereby incorporated by reference into this application.

### BACKGROUND OF THE INVENTION

1. Field of the Invention

The present invention relates to a slide member including a diamond-like-carbon film (DLC film).

2. Description of Related Art

In general, a diamond-like-carbon film is highly hard, and has a flat surface, an excellent wear resistance, and a low friction property due to its solid-lubricating property.

Under an unlubricated condition, a friction coefficient of a surface of an ordinary flat steel is 0.5 or more, and the friction coefficients of a surface of nickel-phosphorus plating, Cr plating, TiN coating, CrN coating and the like which are surface treatment materials according to related arts is approximately 0.4. On the other hand, the friction coefficient of the diamond-like-carbon film is approximately 0.1.

At present, utilizing these excellent properties, application is attempted to slide members and the like used under unlubricated condition such as a manufacturing tool such as a cutting tool like a drill blade, a grinding tool and the like, a die for deforming process, a valve cock, and a capstan roller. On the other hand, sliding under presence of lubrication oil is the main stream for machine components of an internal combustion engine and the like in which maximum possible reduction of mechanical loss is required from the aspects of energy consumption and environment.

In Japanese Patent Application Laid-Open No. Hei 05-169459, a mold for resin or rubber is disclosed in which at least the outermost surface of a hard coating is a diamond-like-carbon film or a hard carbon film including fluorine by 1-20 atm % in the mold for resin or rubber and a component for a forming apparatus for resin or rubber obtained by forming a hard coating on the surface of steel, aluminum alloy, copper alloy and the like.

In Japanese Patent Application Laid-Open No. 2003-26414, an amorphous carbon coating is disclosed which includes a hydrogen-free carbon coating with a film thickness of 0.5 nm to 200 nm formed on a substrate and a hydrogen-containing carbon coating with a hydrogen content of 5 atm % to 25 atm % and a film thickness of 2 to 1000 times of that of the hydrogen-free carbon coating formed on the hydrogen-free carbon coating.

### SUMMARY OF THE INVENTION

A slide member according to an aspect of the present invention includes a substrate; and a diamond-like-carbon film including layers serially stacked in order of a first layer, a second layer and a hard carbon layer, in which the substrate is formed of an alloy steel containing at least one element selected from the group consisting of V, Cr, Nb, Mo, Ta and W, in which the first layer contains at least one element selected from the group consisting of V, Cr, Nb, Mo, Ta and W, and in which the first layer adheres to the substrate.

According to the present invention, the slide member highly reliable over a long period of usage can be provided since the adhesion property between the substrate and the first layer improves.

### BRIEF DESCRIPTION OF THE DRAWINGS

FIG. 1 is a schematic cross-sectional view illustrating a structure of a hard carbon coating arranged on a substrate in a working example.

FIG. 2 is a TEM image showing a cross-sectional structure a hard carbon coating arranged on the substrate in a working example.

FIG. 3 is a schematic cross-sectional view illustrating a structure of a hard carbon coating arranged on the substrate in a comparative example.

### DETAILED DESCRIPTION OF THE PREFERRED EMBODIMENTS

In a manufacturing process for a resin coated cable, it is a long-term issue that resin residues are generated at an outlet of an extrusion die where resin is extruded and a cable core is coated, the residues adhere to the surface of the cable after resin coating, and thereby the yield of a product of the resin coated cable drops.

When a diamond-like-carbon film was formed in the vicinity of an outlet of an alloy steel extrusion die by an unbalanced magnetron sputtering method (UBMS method), the generation amount of the resin residues was drastically reduced. However, when the diamond-like-carbon film was formed on the extrusion die of carbon steel not containing chromium in order to suppress a manufacturing cost of the extrusion die, it was revealed that an adhesion force of the diamond-like-carbon film dropped.

When the diamond-like-carbon film with a high adhesion force can be formed in the vicinity of the outlet of the extrusion die, the yield of a product can be improved and the efficiency can be increased in the manufacturing process of a resin coated cable, and a highly reliable resin coated cable can be provided. When the diamond-like-carbon film with the high adhesion force can be formed not only in the manufacturing process of the resin coated cable but also in sliding parts of a variety of industrial instruments, highly efficient and highly reliable industrial instruments can be provided.

However, when an aluminum alloy or a copper alloy was made a substrate, there was a problem that the adhesion property could not be obtained even when they were made the substrate and the diamond-like-carbon coating including a metal chromium layer and a hard carbon layer was coated thereon because the substrate was soft and chromium element was hardly contained in the substrate.

Also, when an aluminum alloy or a copper alloy was made the substrate and the surface of the substrate was coated with a hard metallic coating such as hard chromium plating and the like by a wet method or with a hard ceramic coating such as chromium nitride and the like by a dry method, there was a problem that the adhesion property as the diamond-like-carbon coating as a whole could not be obtained because crystals formed of metal elements did not grow between the substrate and the hard metal coating or the hard ceramic coating.

Further, even when the substrate was of a hard material of an insulator material such as aluminum nitride or aluminum oxide, there was a problem that bias voltage could not be applied to the substrate and therefore a film could not be formed.

Also, when a vacuum arc deposition method was adopted for forming an intermediate layer (metal layer), there was a problem that the film after formation was poor in flatness because a lot of macro particles were generated, the roughness of the surface was traced or amplified because films were layered on the surface thereof, and the films with excellent flatness could not be obtained which resulted in that breakage and flaking of the diamond-like-carbon coating were liable to be generated when used for the surface of the slide member.

The object of the present invention is to provide a slide member highly reliable over a long period by improving an adhesion property (anti-flaking property) of the diamond-like-carbon coating in the slide member including the diamond-like-carbon coating.

The present invention relates to a slide member including a diamond-like-carbon film highly reliable over a long period by improving the adhesion property (anti-flaking property) of the diamond-like-carbon film against shear.

A diamond-like-carbon film shown in the present embodiment can be applied to a slide member (iron and steel substrate) for a variety of industrial machine components and the like.

The diamond-like-carbon film (hereinafter referred to as “DLC film”) can be formed on a substrate by employing an unbalanced magnetron sputtering (DBMS) method.

In general, the DLC film is a film formed by carbon or hydrogenated carbon in an amorphous state, and is also called as amorphous carbon, hydrogenated amorphous carbon (a-C:H) or the like. For formation of the DLC film, a plasma CVD process forming a film by plasma decomposition of hydrocarbon gas, a vapor-phase process such as an ion beam deposition process and the like using carbon and hydrocarbon ion, an ion plating process vaporizing graphite and the like by arcing, and forming a film, a sputtering process forming a film by sputtering a target under inert gas atmosphere etc. are employed.

Among such various methods for manufacturing the DLC film, the UBMS process is a film forming method in which the balance of magnetic poles arranged on a back surface side of a target is intentionally broken and a non-equilibrium state is brought in a center part and a peripheral part of the target thereby a part of the magnetic lines from the magnetic poles in the peripheral part of the target is extended to the substrate, is the plasma that has been converged in the vicinity of the target is allowed to be easily diffused to the vicinity of the substrate along the magnetic lines, thereby the amount of an ion applied to the substrate during formation of the DLC film can be increased, which results in enabling to form the dense DLC film on an upper surface side of the substrate and enabling to control the structure and the film quality of the DLC film by irradiation of the ion.

Hereinafter, slide members of embodiments in the present invention will be described.

The slide member includes a substrate; and a diamond-like-carbon film including layers serially stacked in order of a first layer, a second layer and a hard carbon layer, in which the substrate is formed of an alloy steel containing at least one element selected from the group consisting of V, Cr, Nb, Mo, Ta and W, in which the first layer contains at least one element selected from the group consisting of V, Cr, Nb, Mo, Ta and W, and in which the first layer adheres to the substrate.

In the slide member, the substrate and the first layer preferably have a same crystal structure.

In the slide member, the second layer contains C element and at least one element selected from the group consisting of V, Cr, Nb, Mo, Ta and W, and the second layer preferably adheres to the first layer.

In the slide member, the first layer and the second layer preferably have a same crystal structure.

In the slide member, the substrate, the first layer and the second layer preferably have a same crystal structure.

In the slide member, it is preferable that concentration of at least one element selected from the group consisting of V, Cr, Nb, Mo, Ta and W decreases and concentration of C element increases toward the hard carbon layer in the second layer.

In the slide member, the hard carbon layer preferably has a mixture of sp² bonding carbon and sp³ bonding carbon.

The slide member can manufacture in the following method:

The method includes the step of forming a diamond-like-carbon film by laminating the first layer, the second layer and the hard carbon layer in this order by an unbalanced magnetron sputtering method on the substrate formed of an alloy steel containing at least one element selected from the group consisting of V, Cr, Nb, Mo, Ta and W.

The detail of the embodiment will be described with referent to the drawings.

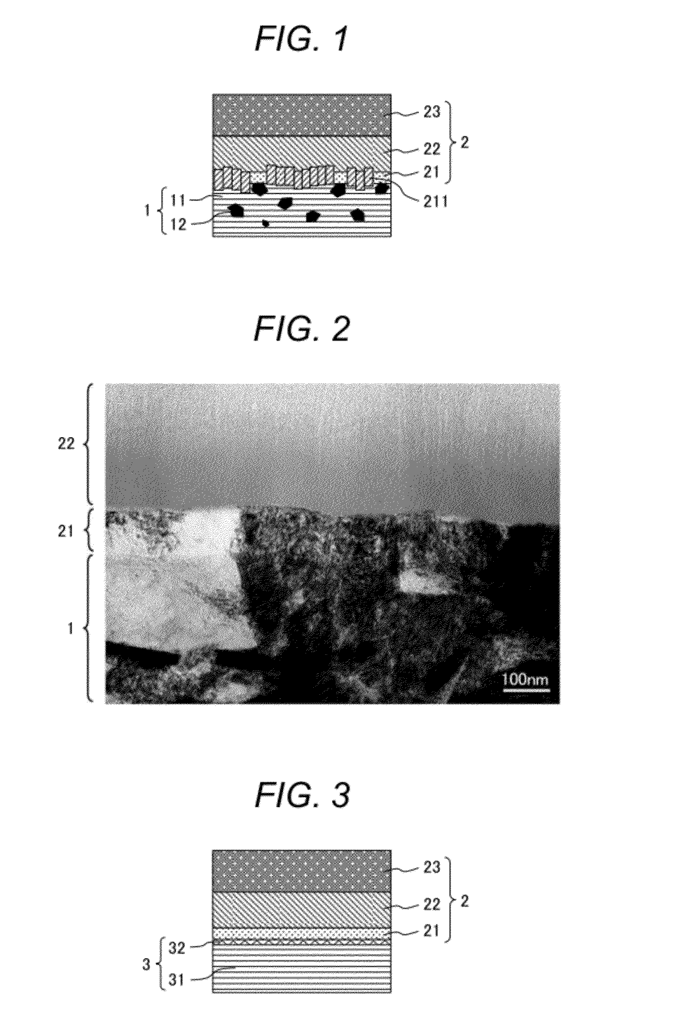

FIG. 1 is a schematic cross-sectional view illustrating a structure of a hard carbon coating arranged on a substrate in a working example.

In FIG. 1, a slide member includes a diamond-like-carbon film 2 constructed of a first layer 21, a second layer 22 and a hard carbon layer 23 from a substrate 1 side on the substrate 1. That is, the diamond-like-carbon film 2 is a set of layers serially stacked in (farther) order of the first layer 21, the second layer 22 and the hard carbon layer 23. The first layer 21 adheres to the substrate 1. In other words, the first layer 21 is stuck on the substrate 1.

In FIG. 1, the slide member preferably has the first layer 21, the second layer 22 and the hard carbon layer 23 serially stacked on an upper surface of the substrate 1. The second layer 22 can improve the adhesion property between the first layer 21 and the hard carbon layer 23. The first layer 21, the second layer 22 and the hard carbon layer 23 compose a diamond-like-carbon film 2. The substrate 1 contains an alloy steel 11 and a metallic carbide 12.

It is preferable that the substrate 1 is formed of the alloy steel 11 containing at least one element selected from the group consisting of V, Cr, Nb, Mo, Ta and W whose crystal structure under normal temperature and normal pressure is a body-centered cubic lattice structure. Because the metallic carbide 12 is formed inside the substrate 1, the hardness of the substrate 1 can be increased, and the adhesion property of the diamond-like-carbon film 2 formed on the substrate 1 becomes excellent as a result.

It is preferable that the first layer 21 contains at least one element selected from the group consisting of V, Cr, Nb, Mo, Ta and W whose crystal structure under normal temperature and normal pressure is the body-centered cubic lattice structure. Also, it is preferable that the first layer 21 contains an element having a crystal lattice constant near to the crystal lattice constant of Fe contained in the substrate 1 and of at least one element selected from the group consisting of V, Cr, Nb, Mo, Ta and W. By containing the element having the crystal lattice constant near to the crystal lattice constant of Fe contained in the substrate 1 and of at least one element selected from the group consisting of V, Cr, Nb, Mo, Ta and W, the same crystal structure easily continues from the substrate 1 toward the first layer 21, and therefore the adhesion property of the diamond-like-carbon film 2 formed on the substrate 1 becomes excellent. The substrate 1 and the first layer 21 have a same crystal structure.

The second layer 22 is formed of a mixture of carbon and a metal or of carbide of a metal. And it is preferable that the content of the metal contained in the second layer 22 decreases from the substrate 1 side toward the hard carbon layer 23 side and the content of the carbon contained in the second layer 22 increases from the substrate 1 side toward the hard carbon layer 23 side. It is preferable that the metal is at least one element selected from the group consisting of V, Cr, Nb, Mo, Ta and W of which crystal structure under normal temperature and normal pressure is the body-centered cubic lattice structure and which is easy in forming carbide, and it is preferable also that the second layer 22 contains an element having a crystal lattice constant near to the crystal lattice constant of at least one element selected from the group consisting of V, Cr, Nb, Mo, Ta and W contained in the first layer 21. By containing the element having a crystal lattice constant near to the crystal lattice constant of at least one element selected from the group consisting of V, Cr, Nb, Mo, Ta and W contained in the first layer 21, a same crystal structure 211 easily continues from the first layer 21 toward the second layer 22, and therefore the adhesion property of the diamond-like-carbon film 2 formed on the substrate 1 becomes excellent. Also, because at least one element selected from the group consisting of V, Cr, Nb, Mo, Ta and W forms carbide inside the second layer 22, the adhesion property of the hard carbon layer 23 formed on the second layer 22 becomes excellent. In other words, it is preferable that the first layer 21 and the second layer 22 have a same crystal structure.

Further, because the element having a crystal lattice constant near to the crystal lattice constant of at least one element selected from the group consisting of V, Cr, Nb, Mo, Ta and W contained in the substrate 1 is contained in the first layer 21 and the second layer 22, a same crystal structure 211 easily continues from the substrate 1 toward the second layer 22, and therefore the adhesion property of the diamond-like-carbon film 2 formed on the substrate 1 becomes excellent. In other words, it is preferable that the substrate 1, the first layer 21 and the second layer 22 have a same crystal structure.

Also, it is preferable that sp² bonding carbon and sp³ bonding carbon are mixingly present in the hard carbon layer 23.

After the diamond-like-carbon film 2 was formed, the hardness of the surface of the diamond-like-carbon film 2 was evaluated by a nano-indentation method (ISO 14577). Also, the adhesion property was evaluated by checking whether or not flaking occurred in the diamond-like-carbon film 2 by pressing a Rockwell diamond indenter into the diamond-like-carbon film 2. Further, a scratch test was performed for evaluating the adhesion force by shear of the diamond-like-carbon film 2. In addition, the cross-section of the diamond-like-carbon film 2 was observed by a transmission electron microscope (TEM), and the crystal state was analyzed by a selected area electron diffraction pattern.

In evaluation of the adhesion property by the pressing-in test of the Rockwell diamond indenter, the conical Rockwell diamond indenter with the tip diameter of 200 μm was pressed in by a testing force of 1471 N (150 kgf), and the state of the crack and flaking of the diamond-like-carbon film 2 around the trace generated by the pressing-in was observed by an optical microscope.

Evaluation of the adhesion force by the scratch test was performed by scanning the surface of the diamond-like-carbon film 2 with the condition of the normal load range of 0-100 N, the loading rate of 100 N/min, and the scanning rate of 10 mm/min using the conical Rockwell diamond indenter with the tip diameter of 200 μm. The scratch damage after the test was observed by an optical microscope, and the normal load value at a position where the local flaking or the continuous flaking that was repeated to the diamond-like-carbon film 2 inside the scratch damage started was determined to be the adhesion force by the shear of the diamond-like-carbon film 2. The adhesion force of the diamond-like-carbon film 2 was calculated by the product of the ratio of the scanning distance to the flaking starting position against the total scanning distance times the maximum load of 100 N.

Evaluation by the nano-indentation method (ISO 14577) was performed with the condition that a Berkovich indenter with the ridge angle of 115 degrees was pressed into the surface of the diamond-like-carbon film 2 for 10 sec to the maximum load of 3 mN, the maximum load was maintained for 1 sec, and thereafter the load was released in 10 sec.

The specimen for observation and analysis of the cross-section of the diamond-like-carbon film 2 by the TEM was manufactured by thinning using an ion thinning apparatus.

It is preferable that the slide member described above is used for a slide member for a variety of the industrial instruments.

Below, the present invention will be described using working examples.

### Working Examples

In FIG. 1 showing a working example, the high-speed tool steel JIS SKH51 material containing chromium element by 4 atm %, the CrMo steel JIS SCM415 material containing chromium element by 1 atm %, the dies steel JIS SKD11 material containing chromium element by 11 atm % were used for the substrate 1. And the respective substrates 1 were finished so that the surface roughness Ra became 0.05 μm. Thereafter, the diamond-like-carbon films 2 were formed by the UBMS process. The diamond-like-carbon films 2 were formed by laminating the first layer 21, the second layer 22 and the hard carbon layer 23 in this order by the UBMS method on the substrate 1. First, the first layer 21 mainly including chromium (Cr) element was formed by applying the bias voltage while introducing inert gas.

Thereafter, the inert gas and the hydrocarbon gas were introduced, and the second layer 22 was formed by applying the bias voltage.

In forming the second layer 22, a chromium carbide layer was formed first, and thereafter the chromium target input power was controlled so as to gradually decrease and the carbon target input power was controlled so as to gradually increase. Here, with respect to the chromium carbide constructing the chromium carbide layer, there are kinds of Cr₃C₂, Cr₇C₃, Cr₂₃C₆ and the like, but the chromium carbide is not limited to them.

Lastly, the inert gas and the hydrocarbon gas were introduced, and the hard carbon layer 23 was formed by applying the bias voltage.

In general, as the hardness of the backing material such as the substrate 1 and the like becomes higher, the adhesion property of the diamond-like-carbon film 2 becomes more excellent. Here, the diamond-like-carbon film 2 represents the stacked film including the first layer 21, the second layer 22 and the hard carbon layer 23.

Various properties of the diamond-like-carbon films 2 of the working examples formed of the constitution described above are shown in Table 1 with a comparative example.

TABLE 1

| | Working Example | | | Comparative |
|---|---|---|---|---|
| | JIS | JIS | JIS | Example |
| Substrate | SKH51 | SCM415 | SKD11 | JIS S50C |
| Cr content | 4 | 1 | 11 | 0 |
| (atm %) | | | | |
| Surface | 0.05 | 0.05 | 0.05 | 0.05 |
| roughness Ra | | | | |
| (μm) | | | | |
| DLC film | 1.2 | 1.2 | 1.2 | — |
| thickness (μm) | | | | |
| DLC hardness | 32 | 32 | 32 | — |
| (GPa) | | | | |
| Adhesion | No flaking | No flaking | No flaking | Flaking in entire |
| property by | | | | periphery around |
| pressing | | | | trace (natural |
| Rockwell | | | | flaking) |
| diamond | | | | |
| indenterin | | | | |
| Adhesion force | 65 | 58 | 53 | 0 |
| by scratch test | | | | (Natural flaking) |
| (N) | | | | |

In Table 1, the working examples contain Cr, but the comparative example does not contain Cr.

Generally, Cr is more likely to form a carbide than Fe. Therefore, cementite is hardly formed on the substrates since the working examples containing Cr in the substrates have chromium carbide formed. On the other hand, the comparative example which does not contain Cr has cementite formed.

The film thicknesses of the diamond-like-carbon films 2 of the working examples formed of the constitution described above were 1.2 μm, the surface roughnesses Ra were 0.05 μm, and the hardnesses of the diamond-like-carbon films 2 by the nano-indentation method were 32 GPa.

As a result of evaluation of the adhesion property by pressing the Rockwell diamond indenter in, flaking of the diamond-like-carbon film 2 around the trace was not observed, and the adhesion property between the substrate 1 and the diamond-like-carbon film 2 was excellent.

As a result of evaluating the adhesion force by the scratch test, the adhesion forces of the diamond-like-carbon films 2 of the working examples showed high values as much as 65 N in JIS SKH51 material, 58 N in JIS SCM415 material, and 53N in JIS SKD11 material.

In FIG. 2, the TEM image of a cross-section of the diamond-like-carbon film 2 is shown.

As a result of the observation and analysis, it was found that crystals formed of Cr elements of the first layer 21 having the body-centered cubic lattice crystal structure made epitaxial growth on top of crystals formed of Fe elements on the surface of the substrate 1 having the body-centered cubic lattice crystal structure when the substrate of JIS SKH51 was used. Also, it is the cause of the epitaxial growth that the lattice constant of the Fe element and the Cr element are generally equal to each other like the lattice constant of Fe element having the body-centered cubic lattice structure is 2.8664 Å whereas the lattice constant of Cr element having the body-centered cubic lattice structure is 2.8839 Å. Thus, because the same crystal structure 211 continues from the surface of the substrate 1 toward the first layer 21, the adhesion property of the diamond-like-carbon film 2 by pressing the Rockwell diamond indenter in and the adhesion force by the shear of the diamond-like-carbon film 2 by the scratch test can be improved. The similar results are obtained even when JIS SCM415 material and JIS SKD11 material are used for the substrate.

According to the working examples, the diamond-like-carbon film 2 with high adhesion force as described above can be provided, and therefore the slide member highly reliable over a long period can be provided. Also, when the slide member according to the present invention is applied to a variety of industrial instruments, high adhesion force is maintained over a long period and the hard carbon layer 23 on the outermost surface causes a low friction effect, and therefore the industrial instruments with a low load and high efficiency can be provided.

Also, according to the working examples, the first layer 21 was made a layer formed of the chromium element and the second layer 22 was made the chromium carbide layer, but they are not to be limited to them. When the substrate 1 is made of an alloy steel containing at least one element selected from the group consisting of V, Nb, Mo, Ta and W even if the substrate 1 does not contain Cr, the first layer 21 is made a layer containing at least one element selected from the group consisting of V, Nb, Mo, Ta and W, the second layer 22 is made a layer containing C element and at least one element selected from the group consisting of V, Nb, Mo, Ta and W, and the crystal lattice structure of the elements contained in the substrate 1 and respective layers is same to each other, a similar effect can be obtained. Also, when the lattice constants of the crystal lattice that the elements contained in the substrate 1 and respective layers construct are near to each other, the epitaxial growth easily occurs between the surface of the substrate 1 and the first layer 21, between the first layer 21 and the second layer 22, or between the surface of the substrate 1, the first layer 21 and the second layer 22, and a more excellent effect can be obtained.

In the hard carbon layer 23 in the working examples, the sp² bonding carbon which is a carbon bond represented by graphite and the sp³ bonding carbon which is a carbon bond represented by diamond are mixingly present. Thus, the diamond-like-carbon film 2 with a low friction coefficient can be provided.

By the combination described above, the diamond-like-carbon films 2 formed in the working examples have high adhesion properties against the substrate 1 and impart low friction property to the slide member. As a result, the slide member with a low load, highly efficient and highly reliable over a long period can be provided.

In the working examples, when JIS SCM415 material with low tempering temperature (tempering temperature: approximately 170° C.) was used for the substrate 1, the temperature condition was set so that the temperature of the diamond-like-carbon film 2 during formation was made the tempering temperature (170° C.) or below so as to suppress softening of the substrate 1.

Also, in the second layer 22 formed between the first layer 21 and the hard carbon layer 23, it is preferable that the Cr carbide layer is formed first and thereafter the Cr concentration continuously decreases and the C concentration continuously increases from the substrate 1 side toward the hard carbon layer 23 side. Further, when the Cr carbide which is a substance constituting the second layer 22 is expressed by CrₓC_{y}, it is preferable that the composition changes little by little from the substrate 1 side toward the hard carbon layer 23 side by changing the ratio of x and y little by little.

According to the UBMS method, cleaning of the surface of the substrate 1 and formation of the first layer 21 through the hard carbon layer 23 can be performed entirely inside a same chamber without breaking the vacuum. Also, the film quality and the structure of the diamond-like-carbon film 2 can be controlled by ion irradiation. Utilizing these advantages, the UBMS method was employed for formation of the diamond-like-carbon film 2 in the working examples. Also, it is preferable to employ the UBMS method, but it is not to be limited to the UBMS method as far as similar advantage and effect are provided.

Thus, by designing the structure from the substrate 1 through the hard carbon layer 23 as described above, the diamond-like-carbon film 2 excellent in adhesion force against the shear can be provided.

### Comparative Example

FIG. 3 is a cross-sectional view of a slide member showing a comparative example.

In the present drawing, the slide member of the comparative example includes the diamond-like-carbon film 2 constructed of the first layer 21, the second layer 22 and the hard carbon layer 23 from a substrate 3 side on the substrate 3.

Here, for the substrate 3, the carbon steel JIS S50C material was used and was finished so that the surface roughness Ra of the substrate 3 became 0.05 μm. Thereafter, the diamond-like-carbon film 2 was formed by the UBMS process in a similar manner done in the working examples.

After the diamond-like-carbon film 2 was formed, the diamond-like-carbon film 2 naturally flaked, and therefore the film thickness, the surface roughness Ra and the hardness of the diamond-like-carbon film 2 could not be evaluated. Evaluation of the adhesion property by pressing the Rockwell diamond indenter in and evaluation of the adhesion force by the scratch test could not be executed either, but flaking of the entire periphery around the trace in evaluation of the adhesion property by pressing the Rockwell diamond indenter in and 0 (zero) N in the adhesion force by the scratch test can be estimated.

As a result of observation of the cross-section of the diamond-like-carbon film 2 in a section where the diamond-like-carbon film 2 partly remained by the TEM, it was revealed that a cementite structure 32 was present on the surface of the substrate 3, the cementite structure 32 impeded crystal growth from the surface of the substrate 3 toward the diamond-like-carbon film 2, and therefore the adhesion property and the adhesion force could not be obtained.

According to the present comparative example, the diamond-like-carbon film 2 with low adhesion force is provided as described above, the diamond-like-carbon film 2 immediately flakes, and therefore the low friction effect by the hard carbon layer 23 on the outermost surface cannot be maintained. Accordingly, when the diamond-like-carbon film 2 of the present comparative example is applied to the slide member for a variety of industrial instruments, the industrial instrument with a low load and high efficiency cannot be provided.

What is claimed is:

1. A slide member comprising:
a substrate; and
a diamond-like-carbon film including layers serially stacked in order of a first layer, a second layer and a hard carbon layer,
wherein the substrate is formed of an alloy steel containing at least one element selected from the group consisting of V, Cr, Nb, Mo, Ta and W,
wherein the first layer contains at least one element selected from the group consisting of V, Cr, Nb, Mo, Ta and W, and
wherein the first layer adheres to the substrate.

2. The slide member according to claim 1,
wherein the substrate and the first layer have a same crystal structure.

3. The slide member according to claim 1,
wherein the second layer contains C element and at least one element selected from the group consisting of V, Cr, Nb, Mo, Ta and W, and
wherein the second layer adheres to the first layer.

4. The slide member according to claim 3,
wherein the first layer and the second layer have a same crystal structure.

5. The slide member according to claim 3,
wherein the substrate, the first layer and the second layer have a same crystal structure.

6. The slide member according to claim 3,
wherein concentration of at least one element selected from the group consisting of V, Cr, Nb, Mo, Ta and W decreases and concentration of C element increases toward the hard carbon layer in the second layer.

7. The slide member according to claim 3,
wherein the hard carbon layer has a mixture of sp² bonding carbon and sp³ bonding carbon.

8. A method for manufacturing a slide member,
the method comprising the step of:
forming a diamond-like-carbon film by laminating a first layer, a second layer and a hard carbon layer in this order by an unbalanced magnetron sputtering method on a substrate formed of an alloy steel containing at least one element selected from the group consisting of V, Cr, Nb, Mo, Ta and W.
